(19) United States
(12) Patent Application Publication
(10) Pub. No.: US 2011/0084411 A1
(43) Pub. Date: Apr. 14, 2011

(54) SEMICONDUCTOR DIE

(75) Inventors: Poh Leng Eu, Petaling Jaya (MY); Lan Chu Tan, Shah Alarm (MY)

(73) Assignee: FREESCALE SEMICONDUCTOR, INC, Austin, TX (US)

(21) Appl. No.: 12/577,731

(22) Filed: Oct. 13, 2009

(51) Int. Cl. H01L 23/28

(52) U.S. Cl. 257/792; 257/E23.116

(57) ABSTRACT

A semiconductor die has a polyimide layer disposed on its top surface. At the corners of the die top, the polyimide layer is roughened or patterned, but not enough such that the die top is exposed. The patterned corners enhance adhesion of a mold compound later disposed on the die top by allowing for enhanced hydrogen bonding between the polyimide layer and the mold compound.

### BACKGROUND OF THE INVENTION

The present invention relates generally to a semiconductor die, and more particularly to a semiconductor die having patterned polyimide on its top surface.

When forming a packaged electronic device, a semiconductor die is electrically connected to a lead frame or substrate to allow the circuit formed in the die to be connected to other electrical circuits. After the die is connected to the substrate or lead frame, a mold compound is formed over the die and the lead frame or substrate to protect the die and interconnections to the lead frame or substrate.

The top surface of the die or die top is often coated with a passivation layer such as SiO₂, SiON or SiN as part of the wafer fabrication process. However, some packaged devices experience interlayer delamination at the corners of the die, as well as top of die delamination, due to stress imposed on the die during testing and other assembly processes such as oxygen plasma treatment. That is, the mold compound may be separated from the die top. This delamination is due to the mold compound not adhering well to the passivation layer on the die top.

It would be advantageous to have a die that would not experience delamination either at the top or corners when subjected to stress.

### BRIEF DESCRIPTION OF THE DRAWINGS

The invention, together with objects and advantages thereof, may best be understood by reference to the following description of the presently preferred embodiments together with the accompanying drawings. In the drawings, like numerals are used for like elements throughout.

FIG. 1 illustrates an enlarged perspective view of a die having a passivation layer on a top surface thereof in accordance with an embodiment of the invention;

FIG. 2 is a partial cross-sectional side view of the die shown in FIG. 1;

FIG. 3 illustrates a greatly enlarged partial cross-sectional side view of the die of FIG. 1 with a mold compound attached thereto in accordance with an embodiment of the invention;

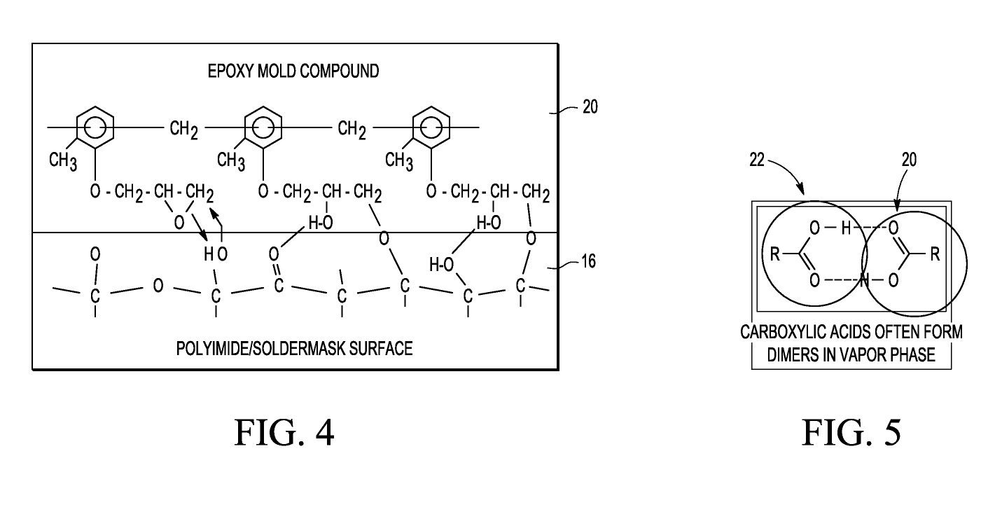

FIG. 4 illustrates the elements of the mold compound bonding with a polyimide layer on the die top in accordance with an embodiment of the present invention;

FIG. 5 illustrates the formation of polar groups between the polyimide layer and the mold compound in accordance with an embodiment of the present invention; and

FIGS. 6A-6C are a table comparing a low K die with a polyimide passivation layer with a low k die with an SiON layer showing the formation of polar groups after oxygen plasma treatment for various ions.

### DETAILED DESCRIPTION OF THE INVENTION

The present invention provides a semiconductor die having a polyimide layer on a top surface of the die. The polyimide layer has patterns at the four corners of the die. The patterned surface of the polyimide layer enhances mold compound adhesion through hydrogen bonding, in addition to the anchoring effects of the patterning. In accordance with the present invention, although the die top is patterned at the corners, a layer of the polyimide remains on the die top at the corners. The patterned corners enhance mold compound adhesion.

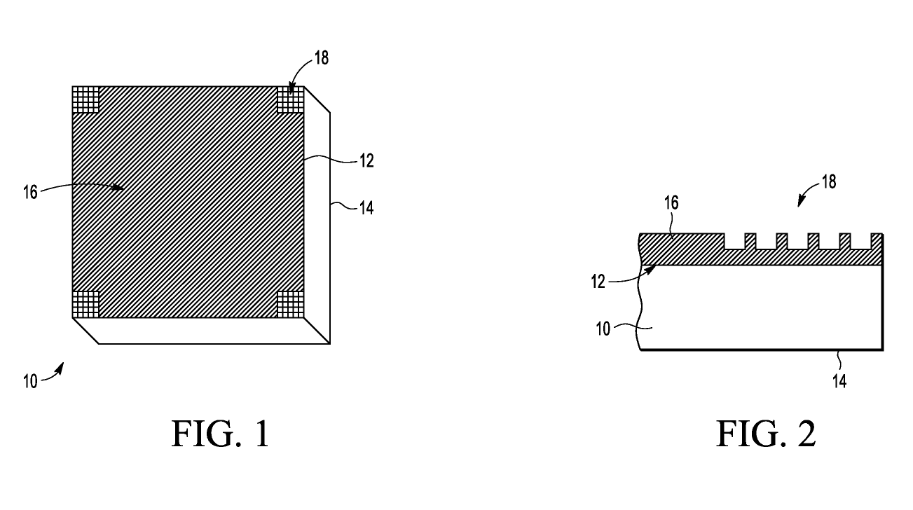

Referring now to FIG. 1, an enlarged perspective view of a semiconductor die 10 is shown. The die 10 comprises silicon and has an integrated circuit formed therein. Although usually rectangular in shape, the die 10 may have other polygonal shapes too. The die 10 has first and second opposing major surfaces 12 and 14, also referred to as top and bottom surfaces. The top surface 12 of the die 10 has a polyimide layer 16 disposed thereon. The polyimide layer 16 may be disposed on the die top 12 by spin or spray coating. The polyimide layer 16 may comprise a polymer that is reacted from a dianhydride and a diamine or tetraamine.

Being rectangular (shown) or polygonal in shape, the die top 12 has a plurality of corners, in this case four (4). The polyimide layer 16 coats the entire surface of the die top 12. At the corners 18, the polyimide layer 16 is roughened or patterned. However, the patterning of the polyimide layer 12 at the corners 18 does not remove all of the polyimide layer. Thus, according to the present invention, the die top 12 is not exposed, even at the corners 18. The roughened or patterned corners 18 enhance adhesion of a mold compound later applied thereto. That is, the roughened corners 18 allow for enhanced hydrogen bonding between the polyimide layer 16 and the mold compound.

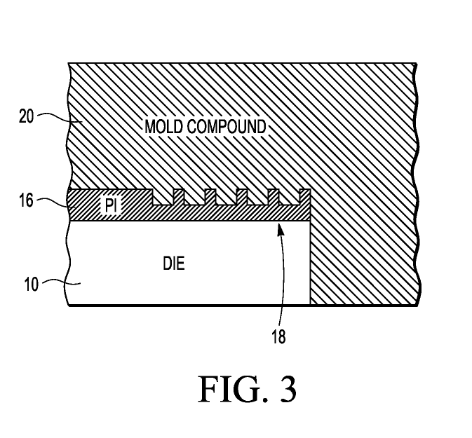

FIG. 2 is a partial, cross-sectional side view of the die 10, illustrating one of the patterned corners 18. As can be seen, the top surface 12 of the die 10 retains a layer of polyimide 16 even at the corners 18. FIG. 2 also shows a mold compound 20 disposed over the die 10 via an encapsulation process. Mold compounds and encapsulation processes are well known to those of skill in the art and need not be described further for a complete understanding of the present invention.

The roughening or patterning of the polyimide layer 12 at the corners 18 may be formed by making grooves in the polyimide layer 16. Such grooves may be formed in a number of ways, such as with a photo-resist exposure and development process, chemical etching, or laser oblation. In one embodiment of the invention, the polyimide layer 16 has a thickness of between about 5 and 10 microns and the grooves have a depth of between about 3 and 8 microns. The grooves may be formed as a series of parallel lines, parallel and perpendicular lines, concentric circles, concentric triangles, etc.

As noted above, the roughened corners 18 provide for better adhesion between the mold compound 20 and the die top 12. More specifically, the roughened corners 18 allow for hydrogen bonding between the polyimide layer 16 and the mold compound 20. With polyimide on the die top 12, analysis has found a good amount of polar group formation after oxygen plasma treatment, which improves mold compound adhesion by hydrogen bonding. The patterned corners 18 also strengthen mold compound adhesion due to the anchoring effect the patterns have with the mold compound.

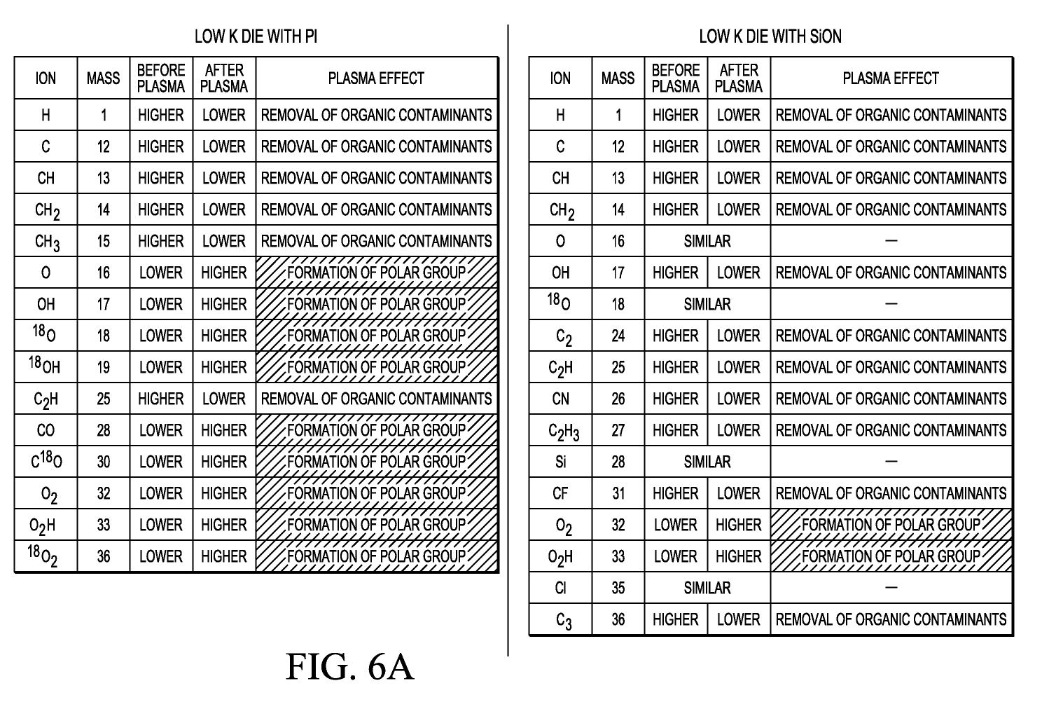

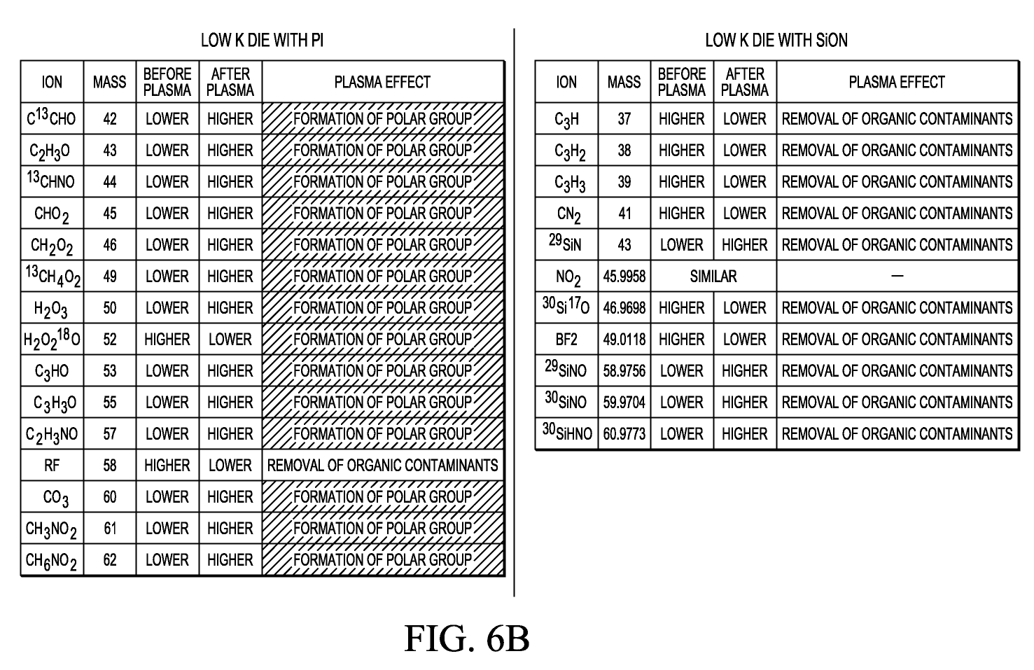

FIGS. 4 and 5 illustrate the hydrogen bonding between the polyimide and the mold compound. FIG. 5 in particular shows the polyimide layer with polar groups 22 bonding with the mold compound 20.

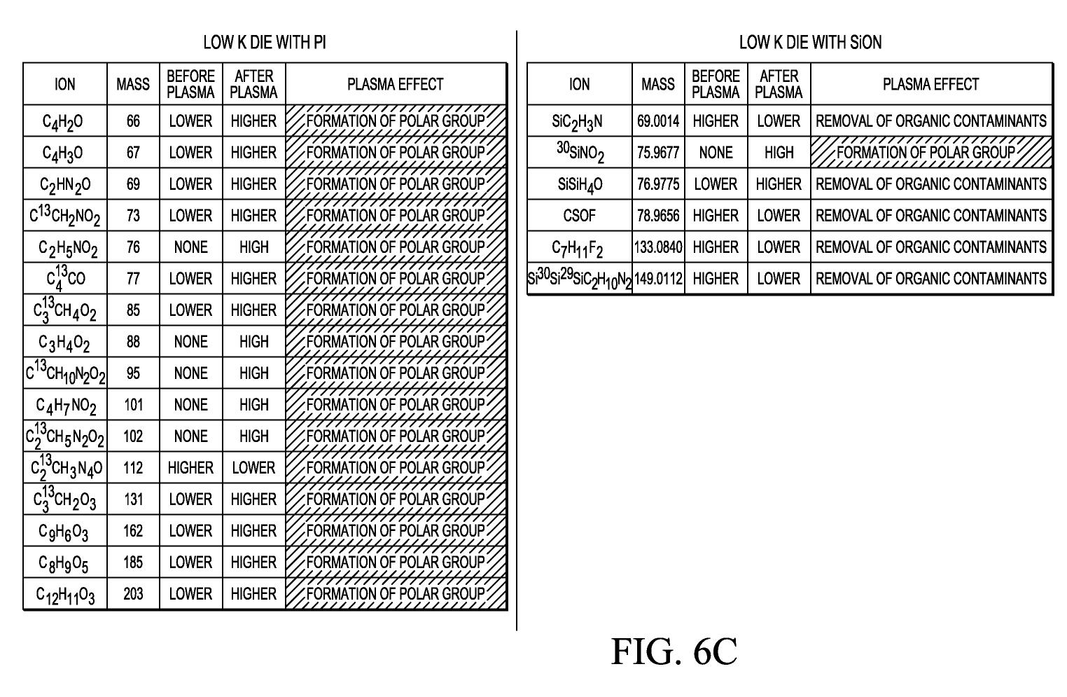

FIGS. 6A-6C are tables comparing a low K die with a polyimide passivation layer with a low k die with a SiON layer. As can be seen from the tables, the low K die with a polyimide layer has more formations of polar groups than the low K die with SiON. Overall, the low K die with a polyimide layer has thirty-nine (39) polar groups as compared to three (3) polar groups on the low K die with SiON.

While embodiments of the invention have been described and illustrated, it will be understood by those skilled in the technology concerned that many variations or modifications in details of design or construction may be made without departing from the present invention.

1. A semiconductor die, comprising:
a polygon shaped silicon die having a plurality of corners and first and second opposing major surfaces; and
a polyimide layer disposed on the first major surface, wherein the polyimide layer is roughened at the plurality of corners but none of the first major surface area at said roughened corners is exposed, and wherein said roughened corners enhance adhesion of a mold compound later applied thereto.

2. The semiconductor die of claim 1, wherein the roughened areas allow for enhanced hydrogen bonding between the polyimide layer and said mold compound.

3. The semiconductor die of claim 2, wherein said roughened corners are formed by making grooves in the polyimide layer.

4. The semiconductor die of claim 3, wherein said grooves are formed with a photo-resist exposure and development process.

5. The semiconductor die of claim 3, wherein said grooves are formed via chemical etching.

6. The semiconductor die of claim 3, wherein said polyimide layer has a thickness of between 5 and 10 microns and said grooves have a depth of between about 3 and 8 microns.

7. The semiconductor die of claim 1, wherein said roughened corners are formed with a shaped pattern.

8. The semiconductor die of claim 7, wherein said shaped pattern is round.

9. The semiconductor die of claim 7, wherein said shaped pattern is rectangular.

10. The semiconductor die of claim 7, wherein said shaped pattern is triangular.

11. A packaged semiconductor device, comprising:
a semiconductor die;
a polyimide layer disposed on a top surface of the die, wherein the polyimide layer is patterned at corners of the die but none of the top surface of the die is exposed by said patterning; and
a mold compound encapsulating the die, wherein the patterned corners provide for enhanced adhesion of the mold compound to the polyimide layer by allowing for enhanced hydrogen bonding between the polyimide layer and the mold compound.

12. The semiconductor die of claim 11, wherein the patterned corners are formed by making grooves in the polyimide layer.

13. The semiconductor die of claim 12, wherein the grooves are formed with a photo-resist exposure and development process.

14. The semiconductor die of claim 12, wherein the grooves are formed via chemical etching.

15. The semiconductor die of claim 12, wherein the polyimide layer has a thickness of between 5 and 10 microns and said grooves have a depth of between about 3 and 8 microns.
